(19) United States
(12) Patent Application Publication
(10) Pub. No.: US 2023/0160962 A1
(43) Pub. Date: May 25, 2023

(54) SIMULATION OF BATTERY CELL CONDITIONS

(71) Applicant: GM GLOBAL TECHNOLOGY OPERATIONS LLC, DETROIT, MI (US)

(72) Inventors: Erik Damon Huemiller, Waterford, MI (US); James Joseph Deininger, Southfield, MI (US); Ryan Curtis Sekol, Grosse Pointe Woods, MI (US); Raffaello Ardanese, Bloomfield Hills, MI (US); Shaomoa Xu, Sterling Heights, MI (US)

(21) Appl. No.: 17/530,743

(22) Filed: Nov. 19, 2021

(51) Int. Cl. G01R 31/36; H01M 10/42

(52) U.S. Cl. CPC G01R 31/3644; H01M 10/4285

(57) ABSTRACT

A device for simulating a battery condition includes a plurality of electrically conductive plates, the plurality of electrically conductive plates including a set of opposing plates having a first plate and a second plate. The device also includes an electrically conductive material extending between the first plate and the second plate, the electrically conductive material in electrical contact with the first plate and the second plate and defining at least part of an electrical path from the first plate to the second plate, the electrically conductive material having a resistance selected to simulate the battery condition in response to activating the device.

### INTRODUCTION

The subject disclosure relates to batteries, and more particularly to simulation of defects and/or short circuits in battery cells.

Battery cells are used in various applications, such as automotive applications (e.g., in electric and hybrid vehicles). Batteries may be subject to various failure modes (e.g., soft short circuits) due to factors such as damage to battery components, excessive heat, dendrite growth and others. Testing for such failure modes can be challenging, and, as such, it is desirable to provide an ability to test for failure modes.

### SUMMARY

In one exemplary embodiment, a device for simulating a battery condition includes a plurality of electrically conductive plates, the plurality of electrically conductive plates including a set of opposing plates having a first plate and a second plate. The device also includes an electrically conductive material extending between the first plate and the second plate, the electrically conductive material in electrical contact with the first plate and the second plate and defining at least part of an electrical path from the first plate to the second plate, the electrically conductive material having a resistance selected to simulate the battery condition in response to activating the device.

In addition to one or more of the features described herein, the device further includes a conductor having a first end in contact with the first plate, the device configured to be activated by putting a second end of the conductor in electrical contact with the second plate, where a distance between the first plate and the second plate is selected to simulate the battery condition when the conductor is in electrical contact with the first plate and the second plate.

In addition to one or more of the features described herein, the battery condition is a soft short circuit occurring at an interior of a battery.

In addition to one or more of the features described herein, the electrically conductive material is a porous material, the resistance of the electrically conductive material is higher than a resistance of the first plate and a resistance of the second plate, and the electrically conductive material defines a diffuse current path between the first plate and the second plate.

In addition to one or more of the features described herein, the electrically conductive material includes one or more current paths between the first plate and the second plate, the one or more current paths having a resistance that is less than the resistance of the electrically conductive material.

In addition to one or more of the features described herein, the first plate, the second plate and the electrically conductive material define a space therein, the space extending from the first plate to the second plate, and the conductor is disposed in the space.

In addition to one or more of the features described herein, the electrically conductive material is a compliant material, and the device is configured to be activated by compressing the electrically conductive material to put the second end in electrical contact with the second plate.

In addition to one or more of the features described herein, the device is configured to be activated by moving the second end into electrical contact with the second plate.

In addition to one or more of the features described herein, the plurality of conductive plates include a plurality of sets of conductive plates, and the conductive material is disposed between opposing plates in each set of conductive plates.

In one exemplary embodiment, a method of simulating a battery condition includes connecting a battery simulation device to a power source, the battery simulation device including a plurality of electrically conductive plates, the plurality of electrically conductive plates including set of opposing plates having a first plate and a second plate. The device also includes an electrically conductive material extending between the first plate and the second plate, the electrically conductive material in electrical contact with the first plate and the second plate and defining at least part of an electrical path from the first plate to the second plate. The method also includes activating the device to simulate the battery condition by performing at least one of: changing a distance between the first plate and the second plate, and moving a conductor disposed between the first plate and the second plate, measuring an electrical signal from the device, and determining a signature associated with the battery condition based on the electrical signal.

In addition to one or more of the features described herein, the distance between the first plate and the second plate and a resistance of the electrically conductive material are selected to simulate the battery condition when the conductor is in electrical contact with the first plate and the second plate.

In addition to one or more of the features described herein, the conductor has a first end in contact with the first plate, and activating the device includes putting a second end of the conductor in electrical contact with the second plate.

In addition to one or more of the features described herein, the electrically conductive material is a porous material having a resistance that is higher than a resistance of the first plate and a resistance of the second plate, the electrically conductive material defining a diffuse current path between the first plate and the second plate.

In addition to one or more of the features described herein, the electrically conductive material is a porous material having a resistance that is higher than a resistance of the first plate and a resistance of the second plate, the electrically conductive material including one or more current paths between the first plate and the second plate, the one or more current paths having a resistance that is less than the resistance of the electrically conductive material.

In addition to one or more of the features described herein, the first plate, the second plate and the electrically conductive material define a space therein, the space extending from the first plate to the second plate, and the conductor is disposed in the space.

In addition to one or more of the features described herein, the electrically conductive material is a compliant material, and activating the device includes compressing the conductive material to put the second end in electrical contact with the second plate.

In addition to one or more of the features described herein, the device is configured to be activated by moving the second end into electrical contact with the second plate.

In one exemplary embodiment, a computer program product includes a computer readable storage medium, the computer readable storage medium having instructions executable by a computer processor to cause the computer processor to perform a method. The method includes connecting a battery simulation device to a power source, the device including a plurality of electrically conductive plates, the plurality of electrically conductive plates including set of opposing plates having a first plate and a second plate. The device also includes an electrically conductive material extending between the first plate and the second plate, the material in electrical contact with the first plate and the second plate and defining at least part of an electrical path from the first plate to the second plate. The method also includes activating the device to simulate the battery condition by performing at least one of: changing a distance between the first plate and the second plate, and moving a conductor disposed between the first plate and the second plate. The method further includes measuring an electrical signal from a battery simulation device, and determining a signature associated with the battery condition based on the electrical signal.

In addition to one or more of the features described herein, the electrically conductive material is a compliant material, and activating the device includes compressing the electrically conductive material to put the conductor in electrical contact with the first plate and the second plate.

In addition to one or more of the features described herein, the first plate, the second plate and the electrically conductive material define a space therein, the space extending from the first plate to the second plate, the conductor is disposed in the space and has a first end in contact with the first plate, and activating the device includes putting a second end of the conductor in electrical contact with the second plate.

The above features and advantages, and other features and advantages of the disclosure are readily apparent from the following detailed description when taken in connection with the accompanying drawings.

### BRIEF DES CRIPTION OF THE DRAWINGS

Other features, advantages and details appear, by way of example only, in the following detailed description, the detailed description referring to the drawings in which:

FIG. 1 depicts an example of a battery cell;

FIG. 2 is a representation of an example of a soft short circuit battery condition;

FIG. 3 depicts an embodiment of a battery simulation device in an inactive state, the battery simulation device including a compliant electrically conductive material and a conductor;

FIG. 4 depicts the battery simulation device of FIG. 3 in an active state;

FIG. 5 depicts an embodiment of a battery simulation device in an inactive state, the battery simulation device including a compliant electrically conductive material and a conductor;

FIG. 6 depicts an embodiment of a battery simulation device in an inactive state, the battery simulation device including an electrically conductive material and a conductor, and a magnetic activation component;

FIG. 7 depicts an embodiment of a battery simulation device in an inactive state, the battery simulation device including a compliant electrically conductive material and a conductor, the electrically conductive material including one or more current paths;

FIG. 8 depicts an embodiment of a battery simulation device in an inactive state, the battery simulation device including sections of a compliant electrically conductive material and a conductor disposed between the sections;

FIG. 9 depicts an embodiment of a battery simulation device including a plurality of sets of conductive plates, each set of conductive plates having a compliant electrically conductive material therebetween;

FIG. 10 depicts an embodiment of a battery simulation device including a plurality of sets of conductive plates, each set of conductive plates having a compliant electrically conductive material therebetween;

FIG. 11 is a block diagram representing a method of manufacturing a battery simulation device and/or simulating a battery condition; and

FIG. 12 depicts a computer system in accordance with an exemplary embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features.

In accordance with one or more exemplary embodiments, methods, devices and systems are provided for simulating a battery cell and simulating a failure mode or other condition of the battery cell. An embodiment of a simulation device is configured to simulate a failure mode or other condition of a battery cell and produce an electromagnetic signature associated with the simulated condition. The electromagnetic signature may be used to monitor the operation of a battery cell, non-destructively test the battery cell to detect failure modes (e.g., soft short circuits or “soft shorts”), and test non-contact sensors targeted for detecting soft shorts or other failure modes. Embodiments include methods of manufacturing simulation devices and simulating failure modes and/or other conditions using simulation devices.

Embodiments described herein present numerous advantages and technical effects. The embodiments provide means for simulating battery conditions in a reliable and repeatable manner, and for effectively determining electrical signatures associated with a soft short or other battery condition. The electrical signatures can be determined with a reduced or eliminated risk of hazards that can occur during conventional testing (e.g., testing of reject cells).

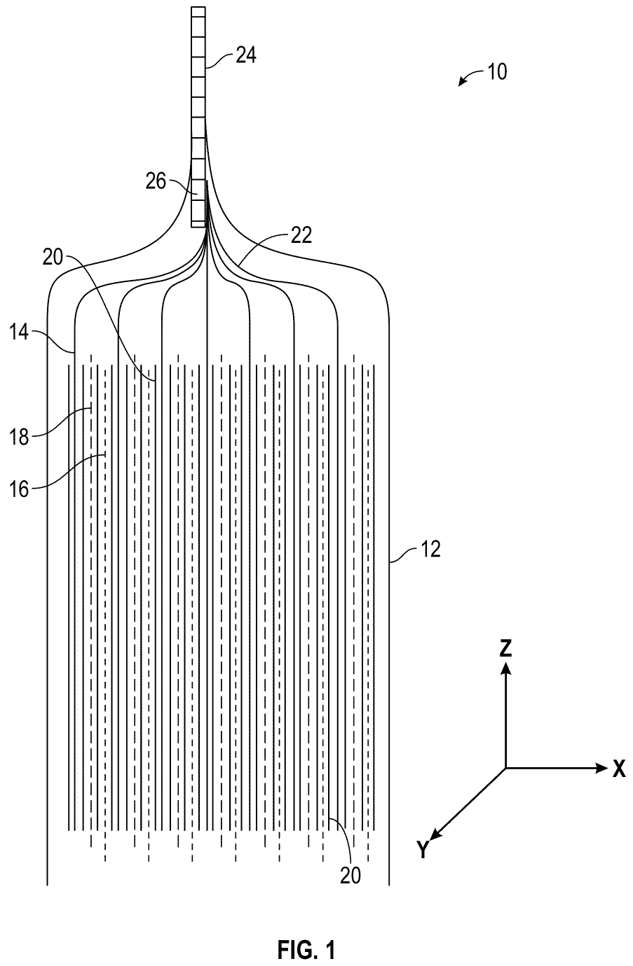

FIG. 1 depicts an example of a pouch-type battery cell 10 that can be simulated via the systems and methods described herein. It is noted that the systems and methods are not limited to simulation of the specific example of FIG. 1, or any other specific battery type. For example, embodiments described herein are also applicable to battery cells having rigid housings.

The battery cell 10 includes a flexible envelope or pouch 12 that is sealed to enclose a plurality of stacked unit cells (cell stack). The pouch 12 may be an aluminum laminated foil or other suitable pouch material. Each unit cell includes a negative electrode or anode 14, and a positive electrode or cathode 16. The anodes and cathodes are made from selected electrically conductive materials and may be configured as thin sheets or foils. Each unit cell also includes a separator 18 made from an electrically insulating material such as a polymer or a ceramic. An active material 20 such as a Lithium material is disposed in the pouch 12 between the various layers of the unit cells.

As shown in FIG. 1, each anode 14 (also referred to as an anode foil) extends away from the unit cells, and the anode foils 14 are attached together as a foil stack 22. The foil stack 22 may be welded together and attached to an electrically conductive tab 24 via a weld 26 or other metal-to-metal joining procedure. The tab 24 in this example is a negative terminal tab. The cathode foils 16 may be similarly welded to a positive terminal tab (not shown) that extends to an exterior of the pouch 12.

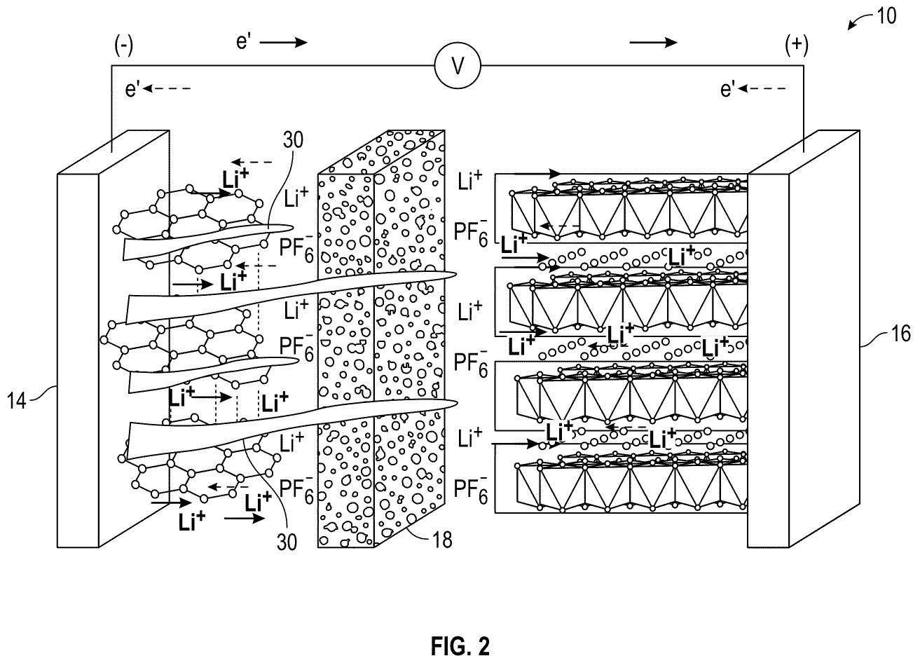

Various battery conditions or failure modes can occur during battery operation. One such failure mode is referred to as a soft short circuit, or simply a “soft short”, which can cause thermal runaway events. FIG. 2 illustrates a portion of an interior of the battery cell 10, and aspects of a condition of the battery cell 10 that can cause a soft short.

In this example, the battery cell 10 is a Lithium ion battery cell, which includes graphite anodes 14, porous separators 18 and Lithium-based cathodes 16. As shown, over the course of battery operation, Lithium dendrites 30 can grow, for example, due to impurities. The dendrites 30 are thin protrusions that can extend through the separator 18. Over time, the dendrites 30 can cause the battery cell 10 to short circuit, which can render the battery cell 10 inoperable and/or result in thermal runaway. Simulation devices and methods described herein may be used to simulate this battery condition, other types of internal shorts (e.g., due to cell damage or tearing) or any other condition (e.g., a hard short, debris on one or more electrodes, etc.).

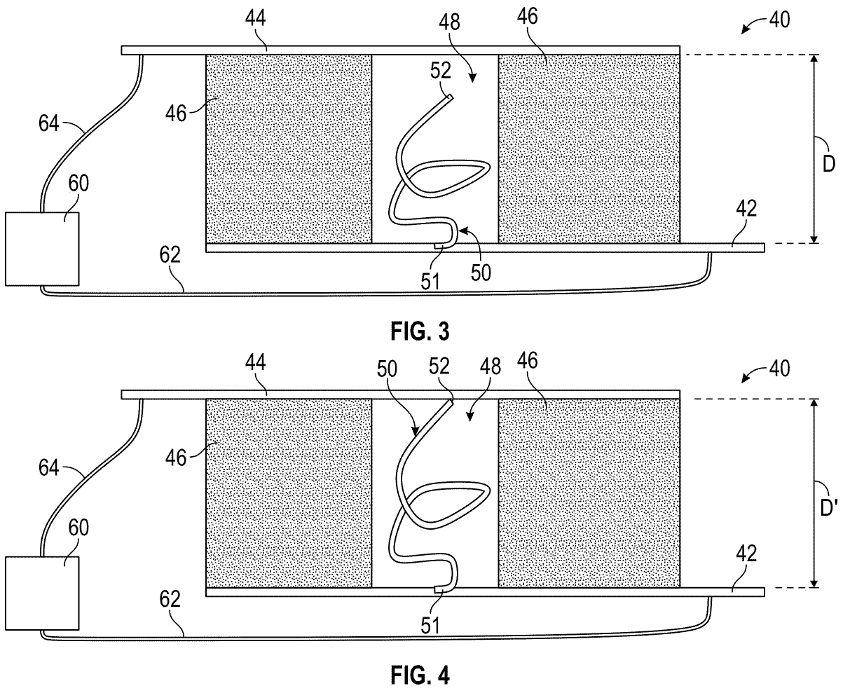

FIG. 3 depicts an embodiment of a simulation device 40 for simulating a battery cell, and simulating failure modes in a battery cell such as soft shorts. The device 40 includes a set of opposing electrically conductive plates, which includes a first plate 42 and a second plate 44. The plates 42 and 44 may be made from any suitable conductive material, such as copper, steel, aluminum and/or other highly conductive material. A material 46 is disposed between the plates 42 and 44, and defines one or more electrical paths for current to flow from one plate to another. As discussed further herein, the electrical paths may include diffuse or bulk current paths through the material 46 and/or defined current paths formed by increasing conductivity in regions of the material 46 (e.g., by depositing layers of more conductive material or impregnating regions of the material volume).

The material 46 may be any suitable conductive material that has a resistance that is greater that the resistances of the plates 42 and 44. In an embodiment, the material 46 is a porous material, such as a foam, that is made from a material that is electrically conducting but has a higher resistance than the plates 42 and 44. The porous material defines a diffuse electrical path between the plates. Any electrically conductive material can be used that has the higher resistance, such as carbon-impregnated polymer, carbon-impregnated rubber, ceramic and others.

The plates 42 and 44 and the material 46 define a space 48 that extends through the device 40. A conductor 50 is fixedly disposed at or near the plate 42 and in electrical contact with the plate 42. The conductor 50 may be made of copper, steel, aluminum, spring steel, or other conductive material. The conductor 50 includes a first end 51 attached to the plate 42 or otherwise disposed in electrical contact with the plate 42, and a second end 52 that extends into the space 48. When in an inactive state (shown in FIG. 3), the second end 52 is held in a position that is away from the plates and the material 46, such that no current can flow through the conductor 50.

To place the device 40 in an active state, the second end 52 may be brought into electrical contact with the plate 44 (e.g., by compressing the material 46 or moving the second end 52). “Electrical contact” between two components refers to a condition wherein an electrical current can be passed between the components. Electrical contact may or may not entail physical contact between components.

Various properties of the device 40 can be selected so as to simulate a failure mode or other condition. The properties may include the type of material 46, the resistivity of the material 46, a distance D between the plates 42 and 44, the material of the plates 42 and 44, conductor material and/or configuration of electrical paths.

For example, the plates 42 and 44 are made from aluminum or other metal, and the conductor 50 is made from a metal such as copper. The material 46 in this example includes a conductive foam, such as carbon-filled polymer or rubber foam. The foam has a resistivity of about 10 Ohms, and the distance D is about 3 mm. Other resistivity values may be selected, such as values between about 0.10 Ohms to at least about 100 Ohms, and other distances may be selected, such as distances in the range of about 1 mm to at least about 25 mm. The resistance of the material 46 can be tuned by modifying properties of the material such as porosity and material type. For example, the material 46 can be made of insulating plastic (or other insulator) with carbon filler percent weights selected to tune the resistance of the cell.

FIG. 3 shows the device 40 in an inactive state, in which the conductor 50 is separated from the plate 44. The device 40 is put into an active state by causing the conductor 50 to be in electrical contact with both plates 42 and 44. In the active state, when voltage is applied, current flows through the conductor 50, simulating a dendrite growing across a battery cell and causing a soft short.

FIG. 4 shows the device 40 in an active state. In this embodiment, the device 40 is put in the active state by compressing the material 46 so that the plates 42 and 44 are brought closer together to reduce the distance D (to a reduced distance D′) such that the second end 52 contacts the plate 44. A testing device 60 may be connected to the plates 42 and 44 via respective leads 62 and 64, to apply a voltage and measure the response of the device 40, such as the change in current or voltage as compared to the inactive state.

The conductor 50 may have any desired length and/or configuration. In the example of FIGS. 3 and 4, the conductor is a wire mounted on the plate 42 and extending at least partially across the space 48. Other lengths and/or configurations may be used.

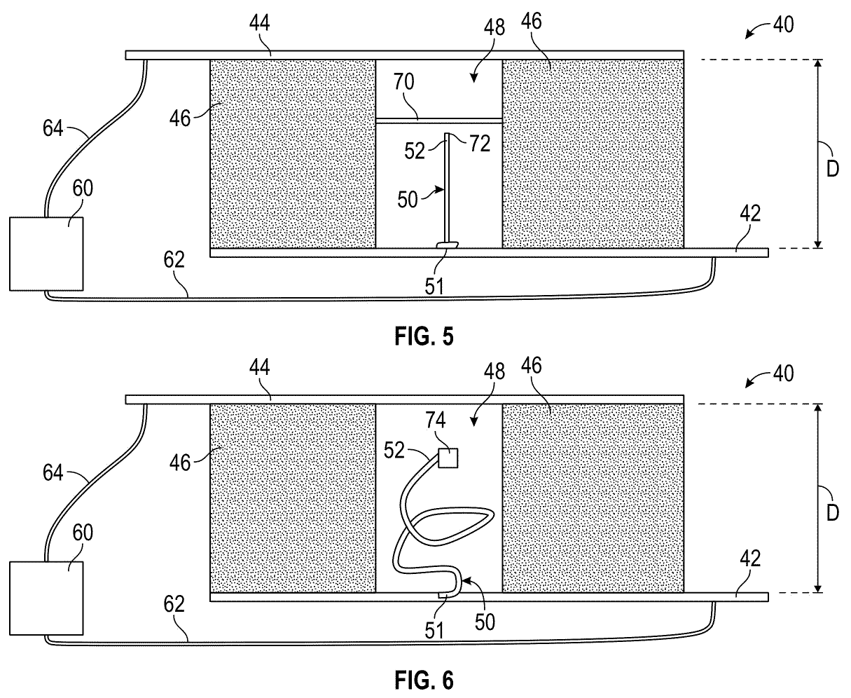

FIG. 5 depicts an embodiment of the device 40 having another configuration of the conductor 50. In this embodiment, the conductor 50 is a rigid length of metal extending into the space 48. A thin sheet of insulating material 70 is attached to the material 46, which simulates a separator (e.g., the separator 18). The conductor 50 has a sharp point 72 at the second end 52, such that when the device 40 is compressed, the conductor 50 will poke through the insulating material 70 and contact the plate 44, simulating a dendrite growing through the separator.

In some embodiments, the device 40 is activated by moving the end 52 of the conductor 50, either in place of compression or in combination with compression. The end 52 may be moved using any desired mechanism.

Referring to FIG. 6, an embodiment of the device 40 includes an activation component 74 affixed at or near the end 52. The activation component 74 includes, for example, a magnetic material or magnet. To activate the device 40 in this embodiment, a magnet can be positioned relative to the plate 44, which attracts the activation component 74, thereby pulling the end 52 into electrical contact with the plate 44.

It is noted that any other suitable mechanism can be used to move the conductor 50 and/or the second end 52, such as mechanical or hydraulic actuating devices. For example, the conductor 50 can be a spring that is held in a compressed position, and a mechanical release can be actuated to release the spring so that the second end 52 contacts the plate 44.

The conductor 50 can be moved to transition the device from an inactive state to an active state, or to transition the device 40 from an active state to an inactive state. For example, the conductor 50 can be moved to put the conductor 50 in electrical contact with the plate 44 as discussed in conjunction with FIG. 6. Alternatively, the conductor 50 can be in electrical contact with both plates by default, and moved to separate an end of the conductor 50 from the plate 42 and/or 44 to deactivate the device 40.

For example, the magnetic activation component 74 may be magnetically attractive to the second plate 44. In an active state, the activation component 74 maintains electrical contact between the second end 52 and the plate 44. The device 40 may be maintained in an inactive state by applying another magnet (not shown) or other suitable component to repel the activation component 74 and cause the second end 52 to separate from the plate 44. The repelling component may be removed to activate the device 40, so that the activation component 74 is no longer repelled and moves to the plate 44.

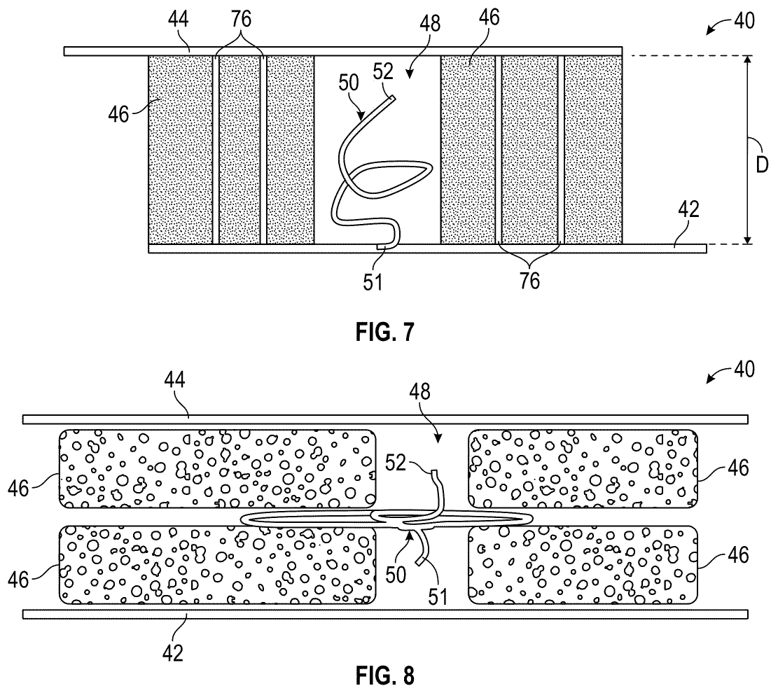

In addition to providing a diffuse electrical path by the material 46, or in place of providing a diffuse path, the material 46 may be configured to provide one or more directed current paths. For example, as shown in FIG. 7, one or more regions 76 extend within the material 46 from the plate 42 to the plate 44. Each region 76 has a lower resistance than the resistance of the surrounding material 46. The regions 76 may be included using any suitable method or process. For example, the material 46 may be made from a plastic or other insulating porous material, and the regions 76 can be portions of the material 46 impregnated with carbon or metallic particles, or layers deposited during additive manufacturing of the material 46.

FIG. 8 depicts an embodiment of the simulation device 40. In this embodiment, the material 46 includes multiple layers or sections. Portions of the conductor 50 are disposed between the sections, and the conductor 50 extends into the space 48 so that the ends 51 and 52 are not in contact with the plates 42 and 44. The material 46 may be compressed to reduce the distance between the plates 42 such that the ends 51 and 52 are put into electrical contact with the plates 42 and 44.

The device 40, in some embodiments, includes multiple sets of plates, each of which includes the material 46. A given set of plates may have one or more spaces 48 therebetween, or may have no spaces.

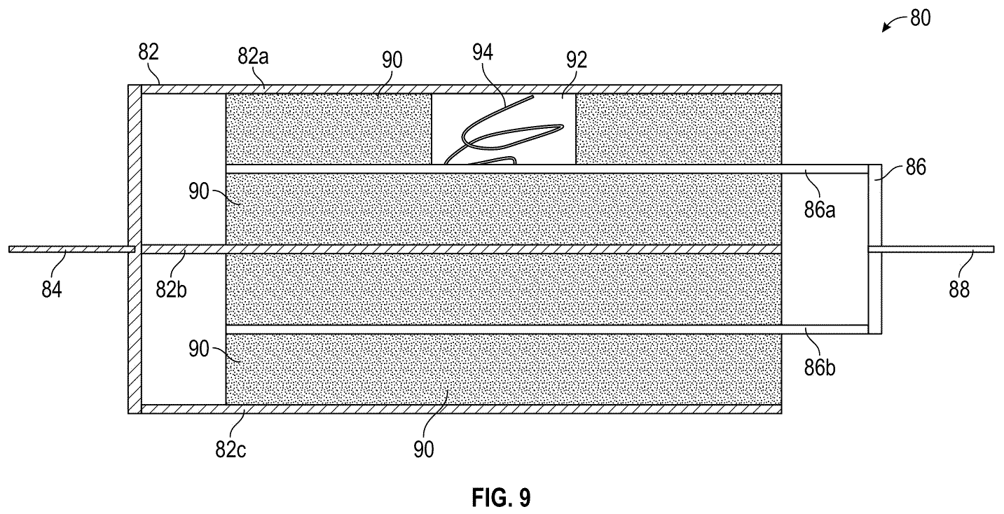

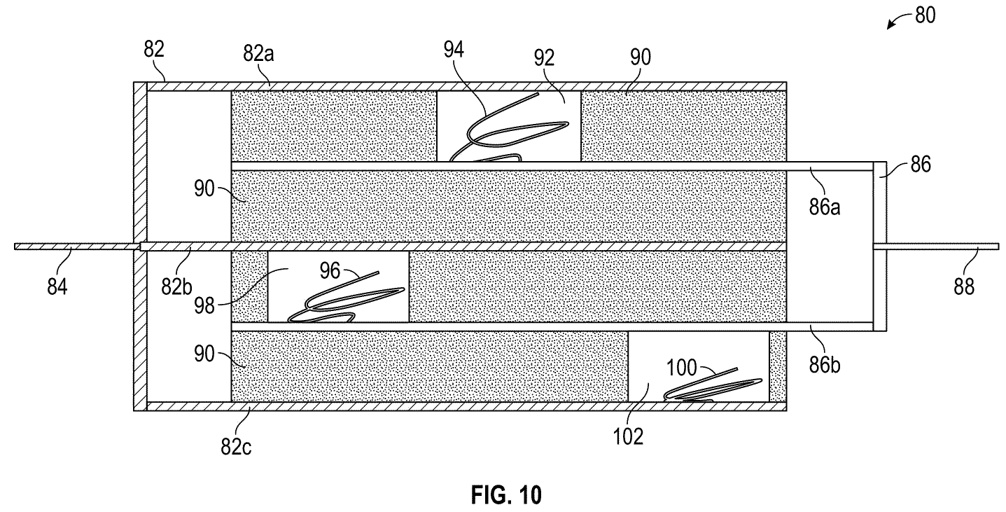

FIGS. 9 and 10 depict embodiments of a simulation device 80 that includes multiple sets of plates, and includes a conductive material 90 between each set of plates, which has a lower resistance than each set of plates and provides a diffuse or directed current path. The material 90 may be similar to the material 46 of FIGS. 3-8. The device 80 is shown in FIGS. 9 and 10 in an active state. It is noted that properties of the material 90 may be the same across the sets of plates, or may be varied as desired (e.g., by varying thickness, material type, resistance, etc.). The simulation device 80 may have a single space 92 and an associated conductor 94 in the space (FIG. 9), simulating a short at a given location, or may have more than one space 92, 98, 102 and associated conductor 94, 96, 100 (FIG. 10) to simulate multiple shorts at various locations. The multiple sets of plates could, for example, simulate multiple unit cells such as those shown in FIG. 1.

The device 80 includes a first plate assembly 82 having three plates 82a, 82b and 82c, which are each connected to a first tab 84. A second plate assembly 86 includes two plates 86a and 86b, which are connected to a second tab 88. The first plate assembly 82 is made of copper and is configured to be negatively charged, and the second plate assembly 86 is made of aluminum and is configured to be positively charged.

A conductive foam or other material 90 is disposed between each set of plates. In FIGS. 9 and 10, four sets of plates are provided. A first set of plates includes plates 82a and 86a, a second set of plates includes plates 86a and 82b, a third set of plates includes plates 82b and 86b, and a fourth set of plates includes plates 86b and 82c. The conductive material 90 may be a compliant foam or other material and may be similar to the conductive material 46 of FIGS. 3-8.

FIG. 9 shows an embodiment having one space 92 and a conductor 94 disposed therein, simulating a short between plates 82a and 86a. FIG. 10 illustrates how multiple shorts (or other conditions) can be simulated at various locations, and includes a space 98 and conductor 96 between plates 82b and 86b, and a space 102 and conductor 100.

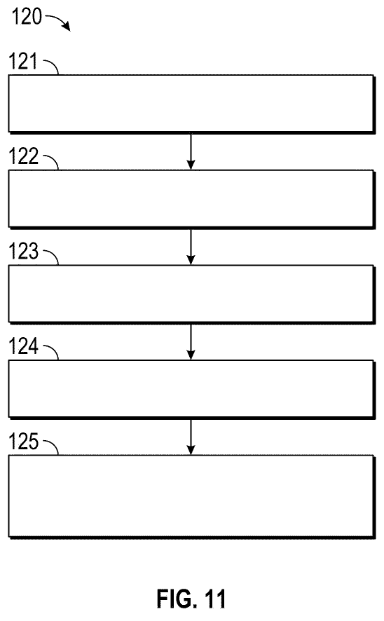

FIG. 11 illustrates an embodiment of a method 120 of manufacturing a simulation device, simulating a battery cell, and/or detecting battery conditions or failure modes. Aspects of the method 120 may be performed by a processor or processors. It is noted the method 120 may be performed by any suitable processing device or system, or combination of processing devices.

The method 120 includes a number of steps or stages represented by blocks 121-125. The method 120 is not limited to the number or order of steps therein, as some steps represented by blocks 121-125 may be performed in a different order than that described below, or fewer than all of the steps may be performed.

Aspects of the method are discussed in conjunction with the device 40 shown in FIGS. 1 and 2, for illustration purposes. The method 120 is not so limited and can be used with any type of simulation device, battery cell, etc.

At block 121, the simulation device 40 is manufactured or assembled. For example, the material 46 is constructed using an additive manufacturing technique such as 3D printing. Resistivity of the material is controlled, for example, by selecting a material having a desired resistivity, or including a conductive material such as metal or carbon as an additive. The material could be, for example, printed from a conducting metal via metal 3D printing or processing of a plastic through a chemical reaction to create a copper or other metallic structure from the 3d printed material. The conductor 50 is attached (e.g., via welding or adhesive) and plates 42 and 44 are positioned and secured in contact with opposing sides of the material 46.

The material 46 could be made in such a way that, under compression, a conductive additive such as carbon increases the conductivity of the material under pressure. This could be done via path planning and lattice optimization.

Printed material may be post processed to tune the electrical properties of the simulation device 40. Post processing includes, for example deposition via sputtering or electro deposition to create conducting paths or regions (e.g., regions 76 shown in FIG. 7).

At block 122, the simulation device 40 is connected to a power source, such as a voltage supply. At block 123, the device 40 is activated by electrically connecting the second end 52 of the conductor 50 to the plate 44. This may be accomplished by deforming the material 46, moving the conductor 50 or otherwise. Activation of the device causes a short circuit through the conductor 50, simulating a soft short.

At block 124, the response of the activated device 40 is measured. At block 125, the response (e.g., voltage measurement, change in voltage) is correlated or otherwise associated with the failure mode. Subsequent testing and/or monitoring of actual battery cells may then be performed, for example, via a non-contact testing device. The testing device outputs signals from the battery, which may be analyzed to detect failure conditions.

The systems and methods described herein may be applicable to various types of batteries. In an embodiment, battery cells evaluated may be cells used in electric and/or hybrid vehicles; however, the systems and methods are not so limited.

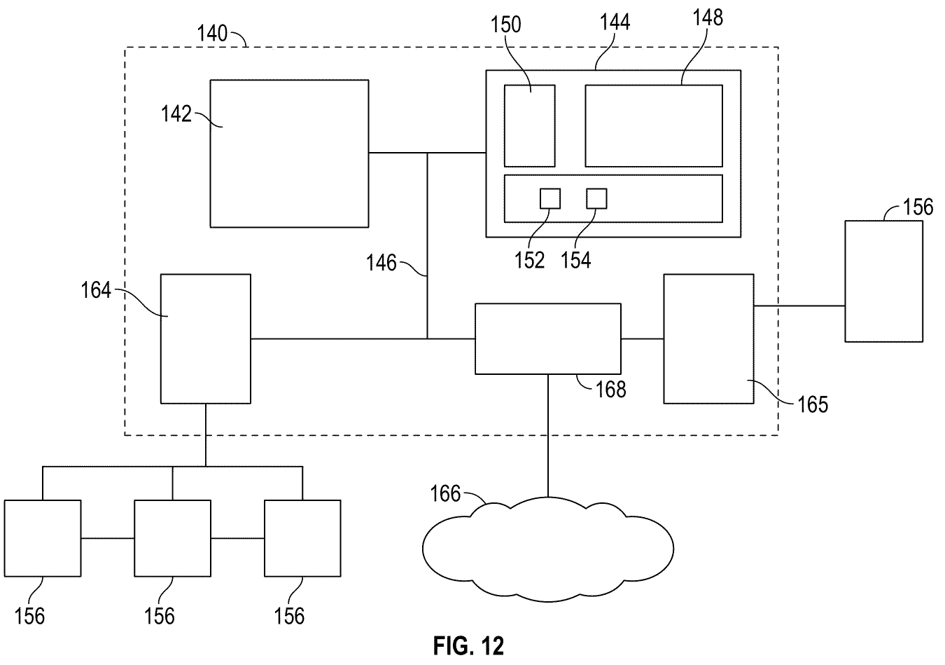

FIG. 12 illustrates aspects of an embodiment of a computer system 140 that can perform various aspects of embodiments described herein. The computer system 140 includes at least one processing device 142, which generally includes one or more processors for performing aspects of image acquisition and analysis methods described herein. Aspects of the computer system 140 may be incorporated into or connected to the testing device 60 or other device for measuring outputs from a simulation device.

Components of the computer system 140 include the processing device 142 (such as one or more processors or processing units), a memory 144, and a bus 146 that couples various system components including the system memory 144 to the processing device 142. The system memory 144 may include a variety of computer system readable media. Such media can be any available media that is accessible by the processing device 142, and includes both volatile and non-volatile media, and removable and non-removable media.

For example, the system memory 144 includes a non-volatile memory 148 such as a hard drive, and may also include a volatile memory 150, such as random access memory (RAM) and/or cache memory. The computer system 140 can further include other removable/non-removable, volatile/non-volatile computer system storage media.

The system memory 144 can include at least one program product having a set (e.g., at least one) of program modules that are configured to carry out functions of the embodiments described herein. For example, the system memory 144 stores various program modules that generally carry out the functions and/or methodologies of embodiments described herein. A module or modules 152 may be included to perform functions related to acquiring measurements of the simulation device. An analysis module 154 may be included for processing of measurements and/or determining signatures associated with various failure modes. The system 140 is not so limited, as other modules may be included. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The processing device 142 can also communicate with one or more external devices 156 as a keyboard, a pointing device, and/or any devices (e.g., network card, modem, etc.) that enable the processing device 142 to communicate with one or more other computing devices. Communication with various devices can occur via Input/Output (I/O) interfaces 164 and 165.

The processing device 142 may also communicate with one or more networks 166 such as a local area network (LAN), a general wide area network (WAN), a bus network and/or a public network (e.g., the Internet) via a network adapter 168. It should be understood that although not shown, other hardware and/or software components may be used in conjunction with the computer system 40. Examples include, but are not limited to: microcode, device drivers, redundant processing units, external disk drive arrays, RAID systems, and data archival storage systems, etc.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A device for simulating a battery condition, the device comprising:
a plurality of electrically conductive plates, the plurality of electrically conductive plates including a set of opposing plates having a first plate and a second plate; and
an electrically conductive material extending between the first plate and the second plate, the electrically conductive material in electrical contact with the first plate and the second plate and defining at least part of an electrical path from the first plate to the second plate, the electrically conductive material having a resistance selected to simulate the battery condition in response to activating the device.

2. The device of claim 1, further comprising a conductor having a first end in contact with the first plate, the device configured to be activated by putting a second end of the conductor in electrical contact with the second plate, wherein a distance between the first plate and the second plate is selected to simulate the battery condition when the conductor is in electrical contact with the first plate and the second plate.

3. The device of claim 1, wherein the battery condition is a soft short circuit occurring at an interior of a battery.

4. The device of claim 1, wherein the electrically conductive material is a porous material, the resistance of the electrically conductive material is higher than a resistance of the first plate and a resistance of the second plate, and the electrically conductive material defines a diffuse current path between the first plate and the second plate.

5. The device of claim 4, wherein the electrically conductive material includes one or more current paths between the first plate and the second plate, the one or more current paths having a resistance that is less than the resistance of the electrically conductive material.

6. The device of claim 2, wherein the first plate, the second plate and the electrically conductive material define a space therein, the space extending from the first plate to the second plate, and the conductor is disposed in the space.

7. The device of claim 6, wherein the electrically conductive material is a compliant material, and the device is configured to be activated by compressing the electrically conductive material to put the second end in electrical contact with the second plate.

8. The device of claim 6, wherein the device is configured to be activated by moving the second end into electrical contact with the second plate.

9. The device of claim 1, wherein the plurality of conductive plates include a plurality of sets of conductive plates, wherein the conductive material is disposed between opposing plates in each set of conductive plates.

10. A method of simulating a battery condition, the method comprising:
connecting a battery simulation device to a power source, the battery simulation device including:
a plurality of electrically conductive plates, the plurality of electrically conductive plates including set of opposing plates having a first plate and a second plate; and
an electrically conductive material extending between the first plate and the second plate, the electrically conductive material in electrical contact with the first plate and the second plate and defining at least part of an electrical path from the first plate to the second plate;
activating the device to simulate the battery condition by performing at least one of: changing a distance between the first plate and the second plate, and moving a conductor disposed between the first plate and the second plate;
measuring an electrical signal from the device; and
determining a signature associated with the battery condition based on the electrical signal.

11. The method of claim 10, wherein the distance between the first plate and the second plate and a resistance of the electrically conductive material are selected to simulate the battery condition when the conductor is in electrical contact with the first plate and the second plate.

12. The method of claim 11, wherein the conductor has a first end in contact with the first plate, and activating the device includes putting a second end of the conductor in electrical contact with the second plate.

13. The method of claim 10, wherein the electrically conductive material is a porous material having a resistance that is higher than a resistance of the first plate and a resistance of the second plate, the electrically conductive material defining a diffuse current path between the first plate and the second plate.

14. The method of claim 10, wherein the electrically conductive material is a porous material having a resistance that is higher than a resistance of the first plate and a resistance of the second plate, the electrically conductive material including one or more current paths between the first plate and the second plate, the one or more current paths having a resistance that is less than the resistance of the electrically conductive material.

15. The method of claim 12, wherein the first plate, the second plate and the electrically conductive material define a space therein, the space extending from the first plate to the second plate, and the conductor is disposed in the space.

16. The method of claim 15, wherein the electrically conductive material is a compliant material, and activating the device includes compressing the conductive material to put the second end in electrical contact with the second plate.

17. The method of claim 14, wherein the device is configured to be activated by moving the second end into electrical contact with the second plate.

18. A computer program product comprising a computer readable storage medium, the computer readable storage medium having instructions executable by a computer processor to cause the computer processor to perform a method comprising:
connecting a battery simulation device to a power source, the device including:
a plurality of electrically conductive plates, the plurality of electrically conductive plates including set of opposing plates having a first plate and a second plate; and
an electrically conductive material extending between the first plate and the second plate, the material in electrical contact with the first plate and the second plate and defining at least part of an electrical path from the first plate to the second plate;
activating the device to simulate the battery condition by performing at least one of: changing a distance between the first plate and the second plate, and moving a conductor disposed between the first plate and the second plate;
measuring an electrical signal from a battery simulation device; and
determining a signature associated with the battery condition based on the electrical signal.

19. The computer program product of claim 18, wherein the electrically conductive material is a compliant material, and activating the device includes compressing the electrically conductive material to put the conductor in electrical contact with the first plate and the second plate.

20. The computer program product of claim 18, wherein the first plate, the second plate and the electrically conductive material define a space therein, the space extending from the first plate to the second plate, the conductor is disposed in the space and has a first end in contact with the first plate, and activating the device includes putting a second end of the conductor in electrical contact with the second plate.
